(19) United States
(12) Patent Application Publication
(10) Pub. No.: US 2012/0176263 A1
(43) Pub. Date: Jul. 12, 2012

(54) CURRENT SWITCH CIRCUIT AND DA CONVERTER

(75) Inventors: Shigeo Imai, Kanagawa (JP); Ippei Akita, Kanagawa (JP); Tetsuro Itakura, Tokyo (JP)

(73) Assignee: KABUSHIKI KAISHA TOSHIBA, Tokyo (JP)

(21) Appl. No.: 13/237,260

(22) Filed: Sep. 20, 2011

(30) Foreign Application Priority Data
Jan. 12, 2011 (JP) 2011-003892

(51) Int. Cl. H03M 1/66; H03K 17/16

(52) U.S. Cl. 341/144; 327/384

(57) ABSTRACT

According to one embodiment, a first switch transistor and a second switch transistor convert an input current to a first current and a second current by performing a switching operation on the basis of differential input voltages, respectively. An input current source supplies the input current to the first and second switch transistors. A noise current generating circuit generates a dummy current to simulate a noise current flowing through the input current source. A third switch transistor and a fourth switch transistor convert the dummy current to a third current and a fourth current by performing a switching operation on the basis of differential input voltages and negatively superimposes the third current and the fourth current on the first and second currents, respectively.

### CROSS-REFERENCE TO RELATED APPLICATIONS

This application is based upon and claims the benefit of priority from Japanese Patent Application No. 2011-3892, filed on Jan. 12, 2011; the entire contents of which are incorporated herein by reference.

### FIELD

Embodiments disclosed herein relate generally to a current switch circuit and a digital-to-analog (DA) converter.

### BACKGROUND

Among current switch circuits, there is a type which converts an input current to differential output currents by performing a switching operation on the basis of differential input voltages. In such current switch circuits, noise or skew called a glitch is generated due to parasitic capacitance during a switching transition period. Since glitch components appear as a high frequency spurious, Spurious Free Dynamic Range (SFDR) is deteriorated.

In analog-and-digital hybrid LSIs or the like, noise is generated in a power supply and a ground of an analog circuit of a DA converter or the like due to the switching noise of a digital circuit. In that instance, if one side of differential output currents of a current switch circuit is intercepted at the time of a normal state, the noises generated in the power supply and ground appear in the differential output currents. This degrades the quality of the output signal.

### BRIEF DESCRIPTION OF THE DRAWINGS

FIG. 1 is a circuit diagram schematically illustrating the structure of a current switch circuit according to a first embodiment;

FIG. 2 is a diagram illustrating waveforms of differential input voltages and differential output currents of the current switch circuit of FIG. 1;

FIG. 3 is a diagram illustrating current paths of the current switch circuit of FIG. 2 during a switching transition period T1;

FIG. 4 is a diagram illustrating current paths of the current switch circuit of FIG. 2 during a normal state period T2;

FIG. 5 is a circuit diagram schematically illustrating the structure of a current switch circuit according to a second embodiment;

FIG. 6 is a circuit diagram schematically illustrating the structure of a current switch circuit according to a third embodiment;

FIG. 7 is a plan view illustrating the layout structure of an input current source 2, a dummy current source 3, and a dummy transistor M_{b0} of FIG. 6;

FIG. 8 is a circuit diagram schematically illustrating the structures of an input current source and a noise current generating circuit of a current switch circuit according to a fourth embodiment;

FIG. 9 is a circuit diagram schematically illustrating the structure of a current switch circuit according to a fifth embodiment;

FIG. 10 is a circuit diagram schematically illustrating the structure of a DA converter according to a sixth embodiment; and

FIG. 11 is a block diagram schematically illustrating the structure of an analog-and-digital hybrid circuit mounted in a DA converter according to a seventh embodiment.

### DETAILED DESCRIPTION

According to one embodiment, a current switch circuit includes a first switch transistor, a second switch transistor, an input current source, a noise current generating circuit, a third switch transistor, and a fourth switch transistor. The first and second switch transistors convert an input current to a first current and a second current by performing a switching operation on the basis of differential input voltages, respectively. The input current source supplies the input current to the first and second switch transistors. The noise current generating circuit generates a dummy current to simulate a noise current flowing through the input current source. The third and fourth switch transistors convert the dummy current to a third current and a fourth current by performing a switching operation on the basis of the differential input voltages, and then negatively superimposes the third current and the fourth current on the first and second currents, respectively.

Herein below, a current switch circuit and a DA converter according to embodiments will be described with reference to the drawings. Furthermore, the invention is not limited to the embodiments.

### First Embodiment

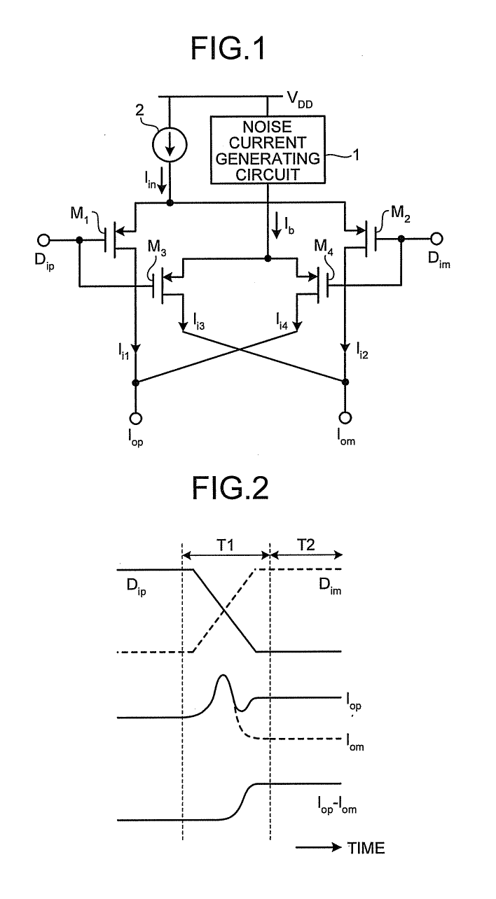

FIG. 1 is a circuit diagram schematically illustrating the structure of a current switch circuit according to a first embodiment.

In FIG. 1, the current switch circuit includes switch transistors M₁ to M₄, a noise current generating circuit 1, and an input current source 2. In the description below, as the switch transistors M₁ to M₄, P-channel field effect transistors are used, for example. However, without being limited to the case described below, N-channel field effect transistors may be used, or alternatively bipolar transistors may be used. Further alternatively, insulated-gate bipolar transistors (IGBTs) may be used.

Herein, the switch transistors M₁ and M₂ (a first switch transistor and a second switch transistor) convert an input current Iᵢₙ to currents Iᵢ₁ and Iᵢ₂ (a first current and a second current) by performing a switching operation on the basis of differential input voltages Dᵢₚ and Dᵢₘ, respectively. The input current source 2 supplies the input current Iᵢₙ to the switch transistors M₁ and M₂. The noise current generating circuit 1 generates a dummy current I_{b} to simulate a noise current flowing through the input current source 2. The switch transistors M₃ and M₄ (a third switch transistor and a fourth switch transistor) convert the dummy current I_{b} to currents Iᵢ₃ and Iᵢ₄ (a third current and a fourth current) by performing a switching operation on the basis of the differential input voltages Dᵢₚ and Dᵢₘ, and negatively superimposes the currents Iᵢ₃ and Iᵢ₄ to the currents Iᵢ₁ and Iᵢ₂, respectively.

That is, sources of the switch transistors M₁ and M₂ are connected to the input current source 2. The differential input voltages Dᵢₚ and Dᵢₘ are applied to gates of the switch transistors M₁ and M₂, respectively.

Sources of the switch transistors M₃ and Mg are connected to the noise current generating circuit 1. The differential input voltages Dᵢₚ and Dᵢₘ are applied to gates of the switch transistors M₃ and M₄, respectively. Drains of the switch transistors M₁ and M₄ are connected to each other. Drains of the switch transistors M₂ and M₃ are connected to each other. The power supplies of the input current source 2 and the noise current generating circuit 1 are connected to a power supply potential V_{DD}.

The current Iᵢ₁ flows in the drain of the switch transistor M₁, the current Iᵢ₂ flows in the drain of the switch transistor M₂, the current Iᵢ₃ flows in the drain of the switch transistor M₃, and the current Iᵢ₄ flows in the drain of the switch transistor Mg. The output current Iₒₚ is produced by superimposing the current Iᵢ₄ on the current Iᵢ₁ and the output current Iₒₘ is produced by superimposing the current Iᵢ₃ on the current Iᵢ₂.

FIG. 2 is a diagram illustrating waveforms of the differential input voltages and differential output currents of the current switch circuit of FIG. 1.

In FIG. 2, it is assumed that the differential input voltage Dᵢₚ is set to a high level and the differential input voltage Dᵢₘ is set to a low level so that the switch transistors M₁ and M₃ are turned off and the switch transistors M₂ and M₄ are turned on. In FIG. 2, it is assumed that the output currents Iₒₚ and Iₒₘ at this point of time are in balance, that is, the output currents Iₒₚ and Iₒₘ are equal to each other.

During a switching transition period T1, the differential input voltage Dᵢₚ shifts to the low level and the differential input voltage Dᵢₘ shifts to the high level so that the switch transistors M₁ and M₃ are turned on and the switch transistors M₂ and M₄ are turned off.

For this reason, during a normal state period T2, the current Iᵢ₁ flows through the switch transistor M₁ and is output as the output current Iₒₚ, and the current Iᵢ₃ flows through the switch transistor M₃ and is output as the output current Iₒₘ. As a result, the differential output current Iₒₚ−Iₒₘ can be obtained.

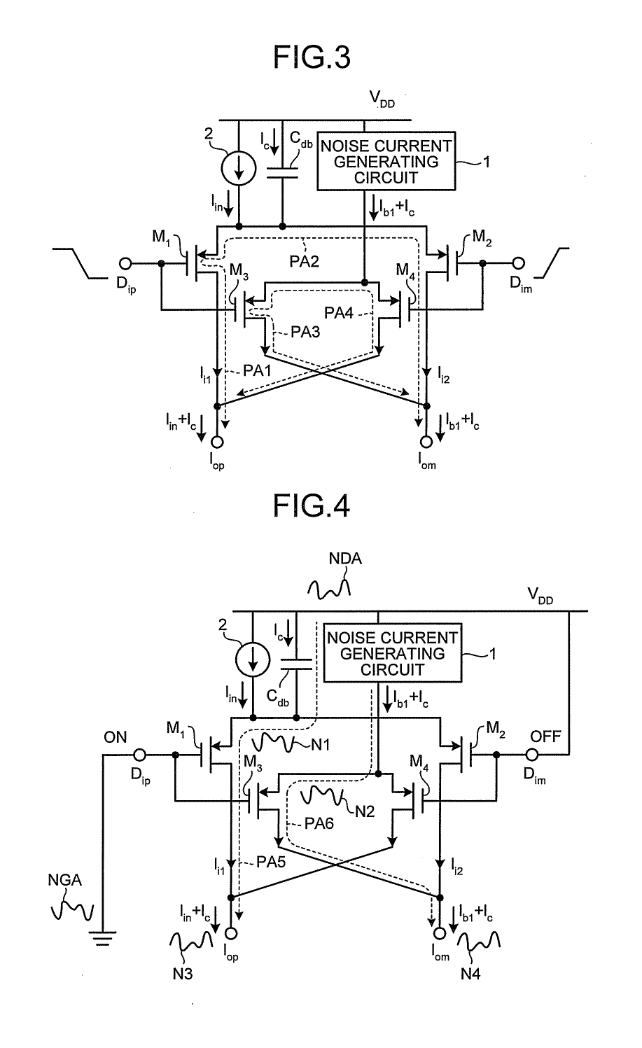

FIG. 3 is a diagram illustrating current paths during the switching transition period T1 in the current switch circuit of FIG. 2.

In FIG. 3, the input current source 2 has a parasitic capacitance C_{db}, and the noise current flowing through the parasitic capacitance C_{db} is represented by I_{c}. The parasitic capacitance C_{db} may correspond to, for example, a drain-bulk capacitance of a transistor serving as the input current source 2. The dummy current I_{b} generated in the noise current generating circuit 1 includes a bias current I_{b1} driving the switch transistors M₃ and M₄ and a noise current I_{c} being equal to the noise current I_{c} flowing through the parasitic capacitance C. In order to prevent the differential output current Iₒₚ−Iₒₘ from becoming zero, a bias current I_{b1} is set to be smaller than the input current Iᵢₙ.

During the switching transition period T1, charging and discharging are performed between the gate and source of each of the switch transistors M₁ and M₂ so that error currents flow in the switch transistors M₁ and M₂. Since an impedance of a path PA1 through which an error current of the switch transistor M₁ flows is different from an impedance of a path PA2 through which an error current of the switch transistor M₂ flows, these error currents differ from each other.

During the switching transition period T1, charging and discharging are performed between the gate and source of each of the switch transistors M₃ and M₄, and error currents flow in the switch transistors M₃ and M₄. In this instance, since the switch transistors M₁ and M₃ are driven together by the differential input voltage Dᵢₚ, the error current of the path PA1 and the error current of the path PA3 become in phase. Furthermore, since the switch transistors M₂ and M₄ are driven together by the differential input voltage Dᵢₘ, the error current of the path PA2 and the error current of the path PA4 also become in phase.

For this reason, the error current of the path PA1 is output as the output current Iₒₚ and the error current of the path PA3 is output as the output current Iₒₘ so that the differential output current Iₒₚ−Iₒₘ is extracted. In this way, the error current of the path PA1 can be eliminated by the error current of the path PA3. Furthermore, the error current of the path PA2 is output as the output current Iₒₘ and the error current of the path PA4 is output as the output current Iₒₚ so that the differential output current Iₒₚ−Iₒₘ can be extracted. In this way, the error current of the path PA2 can be eliminated by the error current of the path PA4.

As a result, during the switching transition period T1, even in a case in which the error current of the path PA1 is different from the error current of the path PA2, the error currents which are output as the output current Iₒₚ and the output current Iₒₘ, respectively are equalized, which can suppress the generation of a glitch.

FIG. 4 is a diagram illustrating current paths during the normal state period T2 in the current switch circuit of FIG. 2. In the example of FIG. 4, the differential input voltage Dᵢₚ is set to the ground potential so that the switch transistors M₁ and M₃ are turned on, and the differential input voltage Dᵢₘ is set to the power supply potential V_{DD} so that the switch transistors M₂ and M₄ are turned off.

In FIG. 4, it is assumed that a power supply noise NDA is generated in the power supply potential V_{DD} and a ground noise NGA is generated in the ground potential. In this instance, the power supply noise NDA and the ground noise NGA are correlated negatively.

Accordingly, if the switch transistor M₁ is turned on, the input current Iᵢₙ flows in the path PA5 so that the current Iᵢ₁ is generated and hence output as the output current Iₒₚ. Furthermore, if the power supply noise NDA is generated, the noise current I_{c} flows through the parasitic capacitance C_{db} so that noise N1 is generated in the source of the switch transistor M₁. In this instance, since the switch transistor M₁ operates like a source follower circuit with respect to the ground, the voltage change at the source side and the voltage change at the ground side come to match each other in terms of alternating current, and the noise current I_{c} flows in the path PA5, which results in noise N3 being generated in the output current If the switch transistor M₃ is turned on, the bias current I_{b1} flows in the path PA6 so that the current I₃ is generated and hence is output as the output current Iₒₘ. Furthermore, if the power supply noise NDA is generated, the noise current I_{c} flows through the noise current generating circuit 1 so that noise N2 is generated in the source of the switch transistor M₃. In this instance, since the switch transistor M₃ operates like a source follower circuit with respect to the ground side, the voltage change at the source side and the voltage change at the ground side match each other in terms of alternating current, and the noise current I_{c} flows in the path PA6, which results in noise N4 being generated in the output current Iₒₘ.

In this instance, since the internal noises N3 and N4 are in phase, the differential output current Iₒₚ−Iₒₘ can be extracted. Accordingly, the noise current I_{c} of the path PA5 can be eliminated by the noise current I_{c} of the path PA6, and hence the noises N3 and N4 originating from the power supply noise NDA and the ground noise NGA can be reduced.

### Second Embodiment

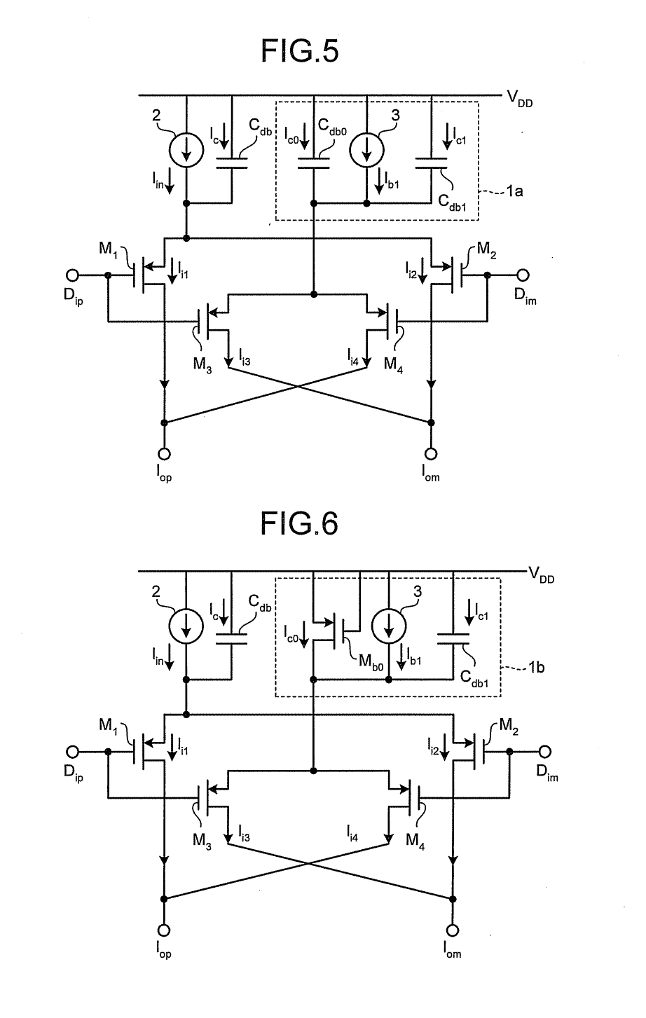

FIG. 5 is a circuit diagram schematically illustrating the structure of a current switch circuit according to a second embodiment.

Referring to FIG. 5, in this current switch circuit, a noise current generating circuit 1a is provided as the noise current generating circuit 1 of FIG. 1. The noise current generating circuit 1a includes a dummy current source 3 and a dummy capacitance C_{db0}. The dummy current source 3 generates a bias current I_{b1} of the switch transistor M₃ and M₄. The dummy capacitance C_{db0} generates a noise current I_{c0}. The dummy current source 3 has a parasitic capacitance C. The parasitic capacitance C_{db1} may correspond to, for example, a drain-bulk capacitance of a transistor which constitutes the dummy current source 3.

The value of the dummy capacitance C_{db0} may be set such that the sum of the value of the dummy capacitance C_{db0} and the value of the parasitic capacitance C_{db1} becomes equal to the value of the parasitic capacitance C_{db}. Since the sum of the noise current I_{c0} flowing in the dummy capacitance C_{db0} and the noise current I_{c1} flowing in the parasitic capacitance C_{db1} is set to be equal to the noise current I_{c} flowing in the parasitic capacitance C_{db}, the noise current I_{c} generated in the differential output current Iₒₚ−Iₒₘ can be eliminated.

Furthermore, since both of the input current Iᵢₙ and the bias current I_{b1} are increased, the frequency characteristic of Power Supply Rejection Ratio (PSRR) can be improved.

### Third Embodiment

FIG. 6 is a circuit diagram schematically illustrating the structure of a current switch circuit according to a third embodiment.

Referring to FIG. 6, in this current switch circuit, a noise current generating circuit 1b is provided in place of the noise current generating circuit 1a of FIG. 5. The noise current generating circuit 1b has a dummy transistor M_{b0} in place of the dummy capacitance C_{db0} of FIG. 5. The dummy transistor M_{b0} is diode-connected to be used as a dummy capacitance.

In this instance, in a case where an input current source 2 and a dummy current source 3 are configured using transistors, the dummy capacitance C_{db0} is implemented with the dummy transistor M_{b0}. Accordingly, the capacitance values can be matched simply by adjusting the width of a gate of the dummy transistor M_{b0}, which makes it easier to match the capacitance values.

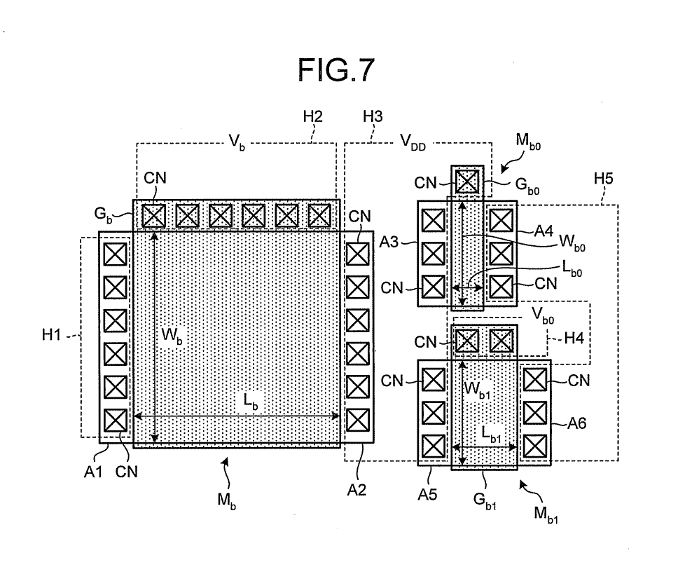

FIG. 7 is a plan view illustrating the layout structure of the input current source 2, the dummy current source 3, and the dummy transistor M_{b0} of FIG. 6.

In FIG. 7, it is assumed that the input current source 2 is configured using a current source transistor M_{b} and the dummy current source 3 is configured using a dummy current source transistor M_{b1}. The current source transistor M_{b} includes a gate electrode G_{b} and active regions A1 and A2. The dummy current source transistor M_{b1} includes a gate electrode G_{b1} and active regions A5 and A6. The dummy transistor M_{b0} includes a gate electrode G_{b0} and active regions A3 and A4. Contacts CN are individually provided on the active regions A1 to A6.

The active region A1 is connected to the sources of the switch transistors M₁ and M₂ through wiring H1. The gate electrode G_{b} is connected to the bias potential V_{b} through wiring H2. The gate electrode G_{b0} and the active regions A2, A3, and A5 are connected to the power supply potential V_{DD} through wiring H3. The gate electrode G_{b1} is connected to a bias potential V_{b0} through wiring H4. The active regions A4 and A6 are connected to the sources of the switch transistors M₃ and M₄ through wiring H5.

The gate length of the gate electrode G_{b} is denoted by L_{b}, and the gate width is denoted by W_{b}. The gate length of the gate electrode G_{b0} is denoted by L_{b0}, and the gate width is denoted by W_{b0}. The gate length of the gate electrode G_{b1} is denoted by L_{b1}, and the gate width is denoted by W_{b1}. When the gate length L_{b} of gate electrode G_{b} increases, output resistance of the current source transistor M_{b} can increase. Even in a case where a load is connected to the input current source 2, the input current Iᵢₙ can be stabilized.

In FIG. 6, when the condition “W_{b}=W_{b0}+W_{b1}” is satisfied, the sum of the value of capacitance of the dummy transistor M_{b0} and the value of the parasitic capacitance C_{db1} can be adjusted to be equal to the value of the parasitic capacitance C_{db0}, and the noise current I_{c} generated in the differential output current Iₒₚ−Iₒₘ can be eliminated.

### Fourth Embodiment

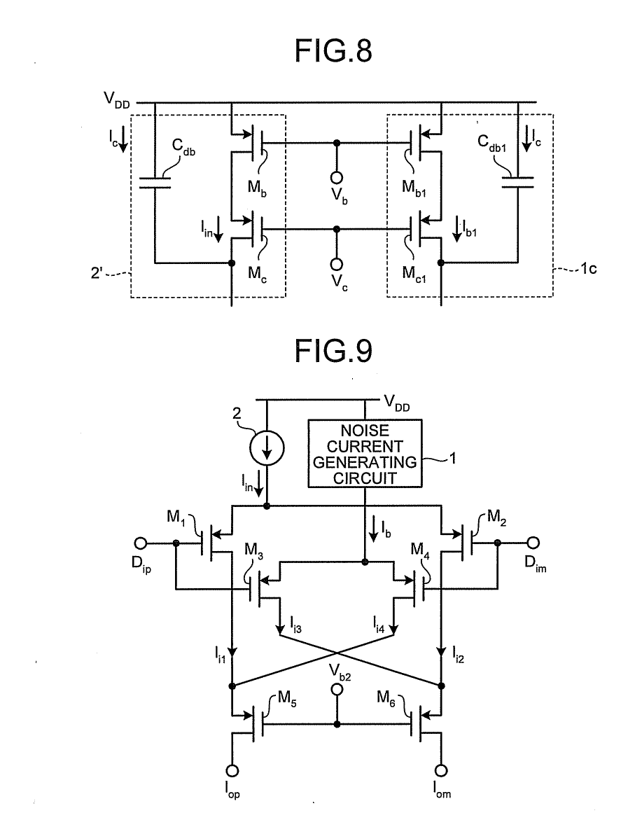

FIG. 8 is a circuit diagram schematically illustrating the structures of an input current source and a noise current generating circuit of a current switch circuit of a fourth embodiment.

Referring to FIG. 8, in this current switch circuit, an input current source 2′ is provided as the input current source 2 of FIG. 1 and a noise current generating circuit 1c is provided as the noise current generating circuit 1 of FIG. 1. The input current source 2′ includes a current source transistor M_{b} and a cascode transistor M. The cascode transistor M_{c} is connected in series with the current source transistor M_{b}. The noise current generating circuit 1c includes a dummy current source transistor M_{b1} and a cascode transistor M_{c1}. The cascode transistor M_{c1} is connected in series with the dummy current source transistor M_{b1}. A bias potential V_{b} is applied to gates of the current source transistor M_{b} and the dummy current source transistor M_{b1} and a bias potential V_{c} is applied to gates of the cascode transistors M_{c} and M_{c1}.

A parasitic capacitance C_{db} is additionally provided between the drain of the cascode transistor M_{c} and the power supply potential V_{DD}. A parasitic capacitance C_{db1} is additionally provided between the drain of the cascode transistor M_{c1} and the power supply potential V_{DD}. The parasitic capacitance C_{db} may correspond to a drain-bulk capacitance of the cascode transistor M. The parasitic capacitance C_{db1} may correspond to a drain-bulk capacitance of the cascode transistor M_{c1}.

The cascode transistors M_{c} and M_{c1} may be equal in size. The bias potential V_{c} may be set such that the cascode transistors M_{c} and M_{c1} operate in a saturation region.

In this way, the values of the parasitic capacitances C_{db} and C_{db1} can be equalized to each other, and the parasitic capacitances of the current source transistors M_{b} and M_{b1} are not demonstrated in the drains of the cascose transistors M_{c} and M_{c1}. For this reason, the noise current I_{c} of the input current source 2′ and the noise current I_{c1} of the noise current generating circuit l_{c} can be equalized, and hence the noise current I_{c} generated in the differential output current Iₒₚ−Iₒₘ can be eliminated.

In addition, since the cascode transistors M_{c} and M_{c1} are connected to the current source transistor M_{b} and the dummy current source transistor M_{b1}, respectively, output resistances of the input current source 2′ and the noise current generating circuit 1c can increase. For this reason, linearity can be improved.

### Fifth Embodiment

FIG. 9 is a circuit diagram schematically illustrating the structure of a current switch circuit according to a fifth embodiment.

Referring to FIG. 9, in this current switch circuit, cascode transistors M₅ and M₆ are added to the structure of FIG. 1. A source of the cascode transistor M₅ is connected to drains of switch transistors M₁ and M₄, and a source of the cascode transistor M₆ is connected to drains of switch transistors M₂ and M₃. A bias potential V_{b2} is applied to gates of the cascode transistors M₅ and M₆.

Accordingly, an output current Iₒₚ is generated from currents Iᵢ₁ and Iᵢ₄ by the cascode transistor M₅, and an output current Iₒₘ is generated from currents Iᵢ₂ and Iᵢ₃ by the cascode transistor M₆.

In this embodiment, due to the provision of the cascode transistors M₅ and M₆, voltage swing can be reduced at the contact point of the switch transistors M₁ and M₄ and the contact point of the switch transistors M₂ and M₃, and output distortion can be reduced.

### Sixth Embodiment

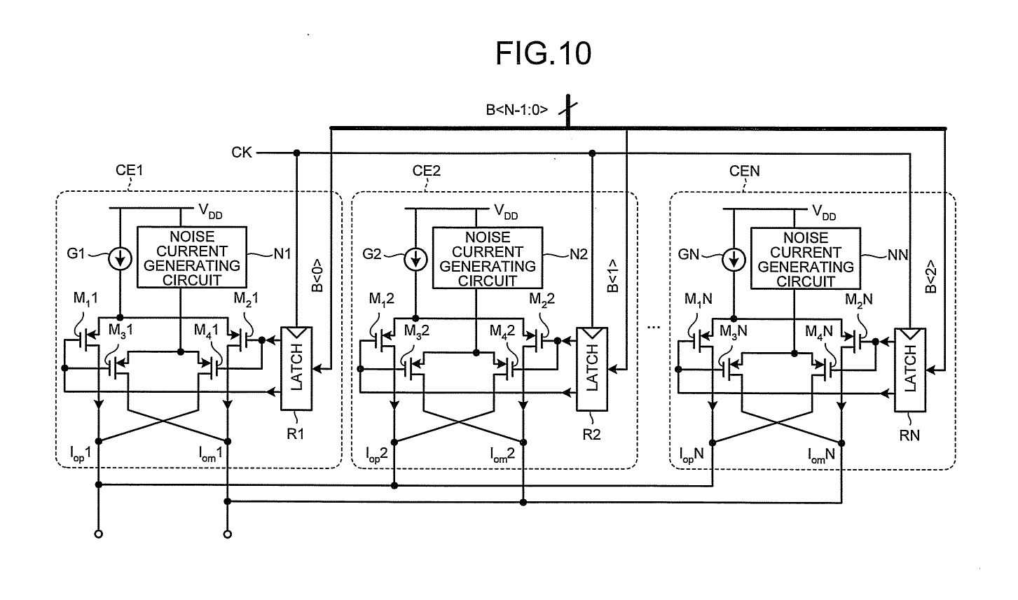

FIG. 10 is a circuit diagram schematically illustrating the structure of a DA converter according to a sixth embodiment.

In FIG. 10, this DA converter includes N (N is an integer of 2 or more) current source cells CE1 to CEN. The current source cells CE1 to CEN are provided with: switch transistors M₁1 to M₁N, M₂1 to M₁N, M₃1 to M₃N, and M₄1 to M₄N; input current sources G1 to GN; noise current generating circuits N1 to NN; and latch circuits R1 to RN; respectively.

The switch transistors M₁1 to M₁N, M₂1 to M₁N, M₃1 to M₃N, and M₄1 to M₄N; the input current sources G1 to GN; and the noise current generating circuits N1 and NN can be configured as in the current switch circuit of FIG. 1. However, the input currents of the input current source G1 to GN can be weighted with multiples (2ⁿ⁻¹) (n is an integer from 1 to N) of 2, respectively. That is, the input current of the input current source G1 can be set to 1 LSB, the input current of the input current source G2 can be set to 2 LSB, and the input current of the input current source GN can be set to 2^{N-1} LSB. The dummy currents output from the noise current generating circuits N1 to NN can be weighted in a similar to the input currents of the input current sources G1 to GN.

n-th bits B<0>, B<1>, . . . , and B<N−1> of N-bit digital data B<N−1:0> are input to latch circuits R1 to RN, respectively. A clock signal CK is commonly input to the latch circuits R1 to RN. In each of the latch circuits R1 to RN, differential input voltages Dᵢₚ and Dᵢₘ corresponding to the values of the n-th bit B<0>, B<1>, . . . , or B<N−1> of the N-bit digital data B<N−1:0> are generated. The generated differential input voltages are output to gates of the corresponding switch transistors M₁1 to M₁N, M₂1 to M₂N, M₃1 to M₃N, or M₄1 to M₄N.

Drains of the switch transistors M₁1 to M₁N and M₄1 to M₄N are connected together. Drains of the switch transistors M₂1 to M₂N and M₃1 to M₃N are connected together.

According to the clock signal CK, n-th bits B<0>, B<1>, . . . , and B<N−1> of the N-bit digital data B<N−1:0> are latched in the latch circuits R1 to RN, respectively. Accordingly, output currents Iₒₚ1 to IₒₚN and Iₒₘ1 to IₒₘN are generated according to the data latched in the latch circuits R1 to RN, respectively in the respective current source cells CE1 to CEN. The output currents Iₒₚ1 to IₒₚN and Iₒₘ1 to IₒₘN are combined so that the N-bit digital data B<N−1:0> is converted into an analog value.

In this embodiment, as each of the current source cells CE1 to CEN, the current switch circuit of FIG. 1 is used. Accordingly, it is possible to eliminate the glitches of the output currents Iₒₚ1 to IₒₚN and Iₒₘ1 to IₒₘN, to eliminate the noises generated in the power supply and ground, and to reduce the distortion and noise of the analog signal which is output from the DA converter.

According to the description above, the DA converter of FIG. 10 has the structure using the current switch circuit of FIG. 1. However, the DA converter may have the structure using the current switch circuit of FIG. 5, FIG. 6, FIG. 8, FIG. 9, or the like that falls within the scope and spirit of the invention. The embodiment of FIG. 10 describes the structure in which the current switch circuit is applied to a current steering-type DA converter, but the current switch circuit may be applied to a mixer circuit used in a frequency converter, modulator, demodulator, or the like.

### Seventh Embodiment

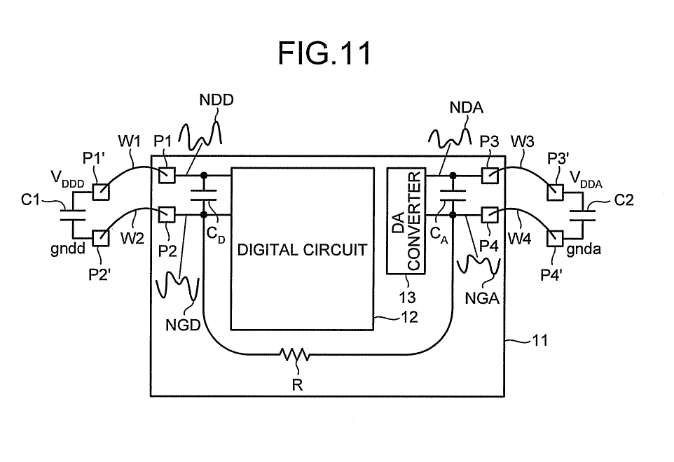

FIG. 11 is a block diagram schematically illustrating the structure of an analog-to-digital hybrid circuit in which a DA converter according to a seventh embodiment is mounted. Referring to FIG. 11, a digital circuit 12 and a DA converter 13 are mounted in a semiconductor chip 11. The DA converter 13 has the structure illustrated in FIG. 10, for example. Alternatively, the DA converter may use the current switch circuit of FIG. 5, FIG. 6, FIG. 8, or FIG. 9. The digital circuit 12 is connected to pad electrodes P1 and P2, and the DA converter 13 is connected to pad electrodes P3 and P4.

The pad electrodes P1 and P2 are connected to each other through a bypass capacitor C_{D}, and the pad electrodes P3 and P4 are connected to each other through a bypass capacitor C_{A}. The pad electrodes P2 and P4 are connected to each other through a resistor R.

The pad electrode P1 and a pad electrode P1′ are connected to each other with a bonding wire W1, and the pad electrode P2 and a pad electrode P2′ are connected to each other with a bonding wire W2. The pad electrode P3 and a pad electrode P3′ are connected to each other with bonding a wire W3, and the pad electrode P4 and a pad electrode P4′ are connected to each other with a bonding wire W4. The pad electrodes P1′ and P2′ are connected to each other through a bypass capacitor C1, and the pad electrodes P3′ and P4′ are connected to each other through a bypass capacitor C2.

In order to isolate the digital circuit 12 and the DA converter 13 from each other, power supplies of the digital circuit 12 and the DA converter 13 are separated. Accordingly, a power supply potential V_{DDD} is applied to the pad electrode P1′ and a ground potential gndd is applied to the pad electrode P2′. In addition, a power supply potential V_{DDA} is applied to the pad electrode P3′ and a ground potential gnda is applied to the pad electrode P4′.

A switching current is generated in the digital circuit 12. For this reason, the power supply potential V_{DDD} and the ground potential gndd change in negative phase each other through finite impedances attributable to inductances of bonding wires W1 and W2 and bypass capacitors C₁ and C_{D}, and the power supply noise NDD and the ground noise NGD are generated in the digital circuit 12.

The power supply noise NDD and ground noise NGD are transferred to the DA converter 13 through a resister R of the semiconductor chip 11, and hence the power supply noise NDA and ground noise NGA are generated at the DA converter side 13. Since the power supply noise NDA and ground noise NGA are transferred to the pad electrodes P3′ and P4′ through bonding wires W3 and W4 or bypass capacitors C2 and C_{A}, the power supply potential V_{DDA} and the ground potential gnda change in negative phase each other.

In this embodiment, the structure of FIG. 10 is used as the DA converter 13, for example so that the glitches of the output currents Iₒₚ1 to IₒₚN and Iₒₘ1 to IₒₘN can be eliminated and the power supply noise NDA and the ground noise NGA also can be eliminated. Accordingly, noise and distortion of the analog signal output from the DA converter 13 can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A current switch circuit comprising:
a first switch transistor and a second switch transistor that convert an input current to a first current and a second current by performing a switching operation based on differential input voltages, respectively;
an input current source that supplies the input current to the first and second switch transistors;
a noise current generating circuit that generates a dummy current to simulate a noise current flowing through the input current source; and
a third switch transistor and a fourth switch transistor that convert the dummy current to a third current and a fourth current by performing a switching operation based on the differential input voltages, and then negatively superimposes the third current and the fourth current on the first and second currents, respectively.

2. The current switch circuit according to claim 1, wherein:
sources of the first and second switch transistors are connected to the input current source;
sources of the third and fourth switch transistors are connected to the noise current generating circuit;
one voltage of the differential input voltages is input to gates of the first and third switch transistors;
the other voltage of the differential input voltages is input to gates of the second and fourth switch transistors;
drains of the first and fourth switch transistors are connected to each other; and
drains of the second and third switch transistors are connected to each other.

3. The current switch circuit according to claim 1, wherein differential output currents are extracted so that during a switching transition period, an error current flowing in the first switch transistor is eliminated by an error current flowing in the third switch transistor and an error current flowing in the second switch transistor is eliminated by an error current flowing in the fourth switch transistor.

4. The current switch circuit according to claim 1, wherein the differential output currents are extracted so that during a normal state period, a noise current flowing in the first switch transistor is eliminated by a noise current flowing in the third switch transistor.

5. The current switch circuit according to claim 1, wherein the dummy current includes a bias current smaller than the input current.

6. The current switch circuit according to claim 5, wherein the noise current generating circuit includes a dummy current source that generates the bias current and a dummy capacitance that is connected in parallel with the dummy current source.

7. The current switch circuit according to claim 6, wherein a value of the dummy capacitance is set such that a noise current flowing in a parasitic capacitance which is parasitic to the input current source is equal to the sum of a noise current flowing in a parasitic capacitance which is parasitic to the dummy current source and a noise current flowing in the dummy capacitance.

8. The current switch circuit according to claim 6, wherein the dummy capacitance is a diode-connected dummy transistor.

9. The current switch circuit according to claim 8, wherein the input current source is configured to use a current source transistor, and the dummy current source is configured to use a dummy current source transistor.

10. The current switch circuit according to claim 9, wherein a width of a gate of the current source transistor equals to the sum of a width of a gate of the dummy current source transistor and a width of a gate of the dummy transistor.

11. The current switch circuit according to claim 5, wherein:
the input current source includes a current source transistor generating the input currents and a first cascode transistor being connected in series with the current source transistor; and
the noise current generating circuit includes a dummy current source transistor generating the bias current and a second cascode transistor being connected in series with the dummy current source transistor.

12. The current switch circuit according to claim 11, wherein the first and second cascode transistors are equal in size to each other.

13. The current switch circuit according to claim 12, wherein a bias potential is set such that the first and second cascode transistors operate in a saturation region.

14. The current switch circuit according to claim 2, further comprising:
a third cascode transistor having a source connected to the drains of the first and fourth switch transistors; and
a fourth cascode transistor having a source connected to the drains of the second and third switch transistors.

15. A DA converter comprising:
N current switch circuits of which input currents are weighted in ratios of 2ⁿ⁻¹ (n is an integer within a range of from 2 to N); and
N latch circuits, each performing a latching operation with respect to an n-th bit of N-bit digital data and outputting the latched bit to the corresponding current switch circuit of the N current switch circuits as the differential input voltage,
wherein the current switch circuit includes:
a first switch transistor and a second switch transistor that convert an input current to a first current and a second current by performing a switching operation based on differential input voltages, respectively;
an input current source that supplies the input current to the first and second switch transistors;
a noise current generating circuit that generates a dummy current to simulate a noise current flowing through the input current source; and
a third switch transistor and a fourth transistor that convert the dummy current to a third current and a fourth current by performing a switching operation based on the differential input voltages, and then negatively superimposes the third current and the fourth current on the first and second currents, respectively.

16. The DA converter according to claim 15, wherein:
sources of the first and second switch transistors are connected to the input current source;
sources of the third and fourth switch transistors are connected to the noise current generating circuit;
one voltage of the differential input voltages is input to gates of the first and third switch transistors;
the other voltage of the differential input voltages is input to gates of the second and fourth switch transistors;
drains of the first and fourth switch transistors are connected to each other; and
drains of the second and third switch transistors are connected to each other.

17. The DA converter according to claim 15, wherein differential output currents are extracted so that during a switching transition period, an error current flowing in the first switch transistor is eliminated by an error current flowing in the third switch transistor, and an error current flowing in the second switch transistor is eliminated by an error current flowing in the fourth switch transistor.

18. The DA converter according to claim 15, wherein the differential output currents are extracted so that during a normal state period, a noise current flowing in the first switch transistor is eliminated by a noise current flowing in the third switch transistor.

19. The DA converter according to claim 15, wherein the dummy current includes a bias current smaller than the input current.

20. The DA converter according to claim 15, further comprising:
a first cascode transistor having a source connected to the drains of the first and fourth switch transistors; and
a second cascode transistor having a source connected to the drains of the second and third switch transistors.
